(19) United States
(12) Patent Application Publication
(10) Pub. No.: US 2026/0259635 A1
(43) Pub. Date: Sep. 3, 2026

(54) INFORMATION PROCESSING METHOD, INFORMATION PROCESSING DEVICE, AND NON-TRANSITORY COMPUTER READABLE RECORDING MEDIUM STORING INFORMATION PROCESSING PROGRAM

(71) Applicant: PANASONIC INTELLECTUAL PROPERTY MANAGEMENT CO., LTD., Osaka (JP)

(72) Inventor: Kazuko NISHIMURA, Kyoto (JP)

(73) Assignee: PANASONIC INTELLECTUAL PROPERTY MANAGEMENT CO., LTD., Osaka (JP)

(21) Appl. No.: 19/656,685

(22) Filed: Apr. 23, 2026

Related U.S. Application Data
(63) Continuation of application No. PCT/JP2024/038416, filed on Oct. 28, 2024.
(60) Provisional application No. 63/546,981, filed on Nov. 2, 2023.

(30) Foreign Application Priority Data
Aug. 6, 2024 (JP) 2024-130145

(51) Int. Cl. G06F 3/04815; G06F 3/04817; G06T 11/60

(52) U.S. Cl. CPC G06F 3/04815; G06F 3/04817; G06T 11/60

(57) ABSTRACT

An information processing method includes: displaying, on a display of an information terminal, a captured image obtained by photographing a predetermined space and a bird’s-eye view corresponding to the predetermined space; receiving selection of two certain points in the bird’s-eye view or the captured image; and displaying, in the captured image, a distance between two points in the captured image corresponding to the two certain points selected in the bird’s-eye view, displaying, in the bird’s-eye view, a distance between two points in the bird’s-eye view corresponding to the two certain points selected in the captured image, or displaying, in the captured image, a distance between the two certain points selected in the captured image.

### FIELD OF INVENTION

The present disclosure relates to a technology of displaying an image.

### BACKGROUND ART

For instance, Patent Literature 1 discloses a technology of performing such a dragging manipulation as to draw a straight line from a desired point to another point included in drawing information so that distance information indicating a direct distance between the points is displayed to overlap the drawing information.

Unfortunately, the conventional technology described above merely displays a distance between two desired points in a drawing and fails to present a distance between two desired points in a captured image to a user, and further shows low accuracy about a depth distance, and therefore needs further improvement. Besides, for confirmation of the distance between the two points, the number of processing steps by a computer may increase, and hence, a burden on the computer may increase.

Patent Literature 1: Japanese Unexamined Patent Publication No. 2022-051601

### SUMMARY OF THE INVENTION

This disclosure has been accomplished to overcome the disadvantages described above, and has an object of providing a technology to enable presentation of a distance between two desired points in a captured image to a user with high accuracy, achieve a reduction in the number of processing steps required by a computer for confirmation of the distance between the two points, and hence achieve a reduction in the burden on the computer.

An information processing method according to an aspect of the present disclosure is an information processing method to be executed by a computer, and includes: displaying, on a display of an information terminal, a captured image obtained by photographing a predetermined space and a bird’s-eye view corresponding to the predetermined space; receiving selection of two certain points in the bird’s-eye view or the captured image; and displaying, in the captured image, a distance between two points in the captured image corresponding to the two certain points selected in the bird’s-eye view, displaying, in the bird’s-eye view, a distance between two points in the bird’s-eye view corresponding to the two certain points selected in the captured image, or displaying, in the captured image, a distance between the two certain points selected in the captured image.

The present disclosure enables presentation of a distance between two desired points in a captured image to a user with high accuracy. The disclosure further achieves a reduction in the number of processing steps required by a computer for confirmation of the distance between the two points, and hence achieves a reduction in the burden on the computer.

### BRIEF DESCRIPTION OF THE DRAWINGS

FIG. 1 is diagram showing an overall configuration of an information processing system in an embodiment.

FIG. 2A illustrates an example design drawing screen image in which a plurality of photographing spots is mapped in the embodiment.

FIG. 2B illustrates an example design drawing screen image in which one photographing spot icon is mapped in the embodiment.

FIG. 3 illustrates an example captured image screen image to be displayed on a display when a photographing spot icon is selected in the embodiment.

FIG. 4 illustrates a comparison display screen image to display a captured image and a design drawing in the embodiment.

FIG. 5 illustrates a comparison display screen image to display a distance between two points in the captured image in the embodiment.

FIG. 6 is a flowchart showing an example of a distance displaying process by a server in the embodiment.

FIG. 7 illustrates a comparison display screen image to display a distance between two points in a captured image in a first modification of the embodiment.

FIG. 8 is a flowchart showing an example of a distance displaying process by a server in the first modification of the embodiment.

FIG. 9 illustrates a comparison display screen image to display a distance between two points in a captured image in a second modification of the embodiment.

FIG. 10 is a flowchart showing an example of a distance displaying process by a server in the second modification of the embodiment.

### DETAILED DESCRIPTION

Knowledge forming the basis of the present disclosure

A user interface has been developed to display, in a two-dimensional design drawing for a worksite or other site, a plurality of photographing spot icons respectively indicating photographing spots where the worksite is actually photographed, and to display an image captured at a certain photographing spot indicated by corresponding one photographing spot icon in response to selection of the one photographing spot icon. This configuration allows a manager of the worksite to grasp a situation of the worksite without visiting the worksite.

It is noted here a user has a demand for, at the time of photographing or after the photographing, confirmation of a distance between two desired points in a captured image having been captured at a photographing spot while seeing the captured image.

Unfortunately, the conventional technology described above merely displays a distance between two desired points in a drawing and fails to present a distance between two desired points in a captured image to the user. Moreover, it is difficult to accurately read out, from an image, distance information about a depth. The conventional technology thus makes it difficult for the user to confirm, with high accuracy, a distance between two desired points in a captured image having been captured at a photographing spot while seeing the captured image. Besides, for confirmation of the distance between the two points, the number of processing steps by a computer may increase, and hence, a burden on the computer may increase.

The following technologies will be disclosed to overcome the disadvantages.

(1) An information processing method according to an aspect of the disclosure is an information processing method to be executed by a computer, and includes: displaying, on a display of an information terminal, a captured image obtained by photographing a predetermined space and a bird’s-eye view corresponding to the predetermined space; receiving selection of two certain points in the bird’s-eye view or the captured image; and displaying, in the captured image, a distance between two points in the captured image corresponding to the two certain points selected in the bird’s-eye view, displaying, in the bird’s-eye view, a distance between two points in the bird’s-eye view corresponding to the two certain points selected in the captured image, or displaying, in the captured image, a distance between the two certain points selected in the captured image.

In this configuration, a distance between two points in the captured image corresponding to two certain points selected in the bird’s-eye view is displayed in the captured image. Alternatively, a distance between two points in the bird’s-eye view corresponding to two certain points selected in the captured image is displayed in the bird’s-eye view. Further alternatively, a distance between two certain points selected in the captured image is displayed in the captured image. This configuration thus enables presentation of a distance between two desired points in a captured image to a user with high accuracy. The configuration further enables presentation of the distance in each of the X-direction and the Y-direction including a depth (Y-direction). Moreover, the configuration that includes the presentation of the distance between the two desired distance in the captured image to the user achieves a reduction in the number of processing steps required by a computer for confirmation of the distance between the two points, and hence achieves a reduction in the burden on the computer.

(2) In the information processing method according to (1) above, the receiving may include receiving the selection of the two certain points in the bird’s-eye view, and the displaying of the distance may include calculating a distance between the two certain points selected in the bird’s-eye view, and displaying, in the captured image, the calculated distance as the distance between the two points in the captured image.

This configuration includes calculating the distance between the two certain points in the bird’s-eye view, and thus enables calculation of an exact distance. The configuration further includes displaying, in the captured image, the calculated distance as the distance between the two points in the captured image, and thus enables presentation of an exact distance between two desired points in the captured image to the user.

(3) In the information processing method according to (1) above, the receiving may include receiving the selection of the two certain points in the captured image, and the displaying of the distance may include calculating the distance between the two points in the bird’s-eye view corresponding to the two certain points selected in the captured image, and displaying the calculated distance in the bird’s-eye view.

This configuration includes calculating the distance between the two points in the bird’s-eye view corresponding to the two certain points selected in the captured image, and thus enables calculation of an exact distance. The configuration further includes displaying the calculated distance in the bird’s-eye view, and thus enables presentation of an exact distance between two desired points in the captured image to the user.

(4) In the information processing method in (1) above, the receiving may include receiving the selection of the two certain points in the captured image, and the displaying of the distance may include calculating the distance between the two points in the bird’s-eye view corresponding to the two certain points selected in the captured image, and displaying the calculated distance in the captured image.

This configuration includes calculating the distance between the two points in the bird’s-eye view corresponding to the two certain points selected in the captured image, and thus enables calculation of an exact distance. The configuration further includes displaying the calculated distance in the captured image, and thus enables presentation of an exact distance between two desired points in the captured image to the user.

(5) In the information processing method according to any one of (1) to (4) above, the captured image may include an omnidirectional image.

This configuration enables acquisition of a captured image around a photographing spot by changing a sightline direction, and hence allows confirmation of a situation of the predetermined space in detail.

(6) In the information processing method according to (5) above, the displaying of the captured image and the bird’s-eye view may include, in a case where a sightline direction is changed, rotating the bird’s-eye view so that the sightline direction agrees with, in the bird’s-eye view, a direction toward an upper side of the bird’s-eye view. The information processing method according to (5) may further include displaying, in the bird’s-eye view, a graphic such as an arrow shape, a triangular shape, or other shape denoting the sightline direction to explicitly show the sightline direction in the bird’s-eye view.

This configuration allows the user to confirm, in the bird’s-eye view, the sightline direction in the captured image.

(7) The information processing method according to any one of (1) to (6) above, the displaying of the captured image and the bird’s-eye view may include displaying one captured image among a plurality of captured images having been continuously captured. The information processing method may further include displaying a switch icon for switching from the one captured image being displayed to a captured image captured before the one captured image or to a captured image captured after the one captured image. The displaying of the distance may include, in a case where the switch icon is selected, switching to the captured image captured before the one captured image or to the captured image captured after the captured image, and displaying the distance in the captured image resulting from the switching.

Even in a case where one captured image being displayed is switched to a captured image captured before the one image or to a captured image captured after the one image, the configuration enables, to the user, presentation of a distance between two desired points in the captured image resulting from the switching.

(8) In the information processing method according to any one of (1) to (7) above, the bird’s-eye view may include a two-dimensional plan view of the predetermined space, and the receiving may include receiving the selection of the two certain points in a horizontal direction in the two-dimensional plan view.

This configuration enables presentation of the distance between the two desired points in the horizontal direction in the captured image to the user with high accuracy.

(9) In the information processing method according to any one of (1) to (7) above, the bird’s-eye view may include a three-dimensional simulation image of the predetermined space or a two-dimensional side view of the predetermined space, and the receiving may include receiving the selection of the two certain points in a vertical direction in the three-dimensional simulation image or the two-dimensional side view.

This configuration enables presentation of the distance between the two desired points in a vertical direction in the captured image to the user with high accuracy.

Moreover, the disclosure can be realized as: the information processing method executing the above-described distinctive ways; and a information processing device including each distinctive feature corresponding to the distinctive ways executed by the information processing method. Additionally, the disclosure can be realized by a computer program causing a computer to execute the distinctive ways included in the information processing method. From these perspectives, the same advantageous effects as those of the information processing method are achievable in the following other aspects.

(10) An information processing device according to another aspect of the present disclosure includes a processor. The processor is configured to: display, on a display of an information terminal, a captured image obtained by photographing a predetermined space and a bird’s-eye view corresponding to the predetermined space; receive selection of two certain points in the bird’s-eye view or the captured image; and display, in the captured image, a distance between two points in the captured image corresponding to the two certain points selected in the bird’s-eye view, display, in the bird’s-eye view, a distance between two points in the bird’s-eye view corresponding to the two certain points selected in the captured image, or display, in the captured image, a distance between the two certain points selected in the captured image.

(11) An information processing program according to another aspect of the present disclosure includes causing a computer to: display, on a display of an information terminal, a captured image obtained by photographing a predetermined space and a bird’s-eye view corresponding to the predetermined space; receive selection of two certain points in the bird’s-eye view or the captured image; and display, in the captured image, a distance between two points in the captured image corresponding to the two certain points selected in the bird’s-eye view, display, in the bird’s-eye view, a distance between two points in the bird’s-eye view corresponding to the two certain points selected in the captured image, or display, in the captured image, a distance between the two certain points selected in the captured image.

(12) A non-transitory computer readable medium according to another aspect of the present disclosure stores an information processing program described in (11) above.

An embodiment of this disclosure will be described with reference to the accompanying drawings. The embodiment which will be described below represents a specific example of the disclosure. Numeric values, shapes, constituent elements, steps, and the order of the steps described below in the embodiment are mere examples, and thus should not be construed to delimit the disclosure. Moreover, constituent elements which are not recited in the independent claims each showing the broadest concept among the constituent elements in the embodiments are described as selectable constituent elements. The respective contents are combinable with each other in the embodiment.

### Embodiment

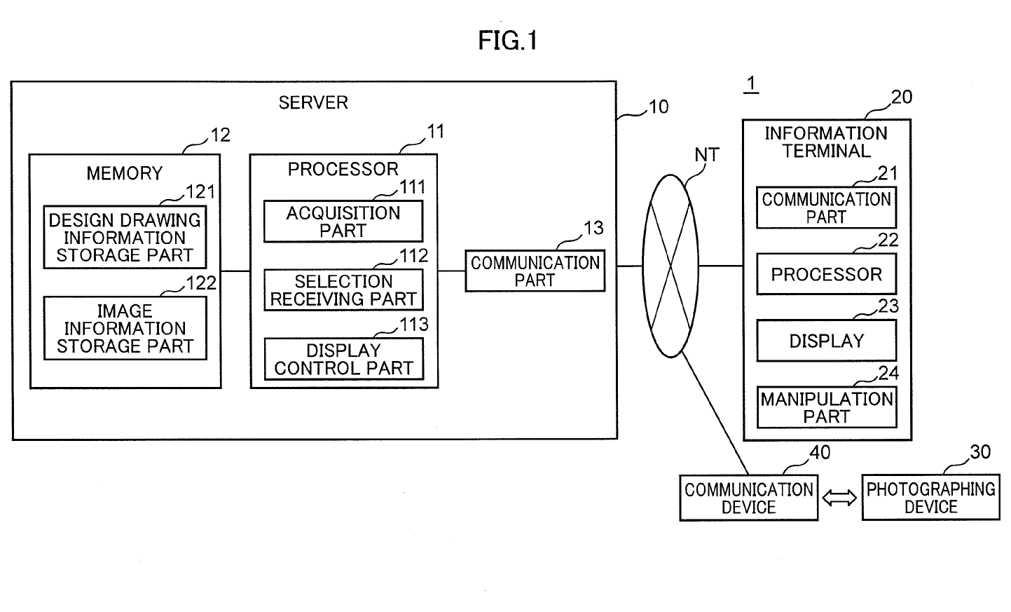

FIG. 1 is diagram showing an overall configuration of an information processing system 1 in an embodiment.

The information processing system 1 is configured to: display, on a display 23 of an information terminal 20, a captured image obtained by photographing a predetermined space and a bird’s-eye view corresponding to the predetermined space; receive selection of two certain points in the bird’s-eye view; and display, in the captured image, a distance between two points in the captured image corresponding to the two certain points selected in the bird’s-eye view. The information processing system 1 includes a server 10, the information terminal 20, a photographing device 30, and a communication device 40.

The server 10 is an example of an information processing device and a computer. The server 10, the information terminal 20, and the communication device 40 are communicably connected to one another via a network NT. The network NT includes, for example, the internet. The server 10 includes, for example, a cloud server including one or more computers. However, this is a mere example, and the server 10 may include an edge server, or may be mounted to the information terminal 20. A configuration in which the server 10 is mounted to the information terminal 20 corresponds to an example configuration of the information terminal 20 in the form of an information processing device.

The information terminal 20 is carriable by a user. The user is, for example, a manager of a predetermined space to be photographed by the photographing device 30. The predetermined space is, for example, a construction site. However, this is a mere example, and the predetermined space may be a worksite, a factory, a shop or store, or an office. The information terminal 20 may include a portable computer, e.g., a smartphone or a tablet computer, or may include a stationary computer. The information terminal 20 is configured to display an image on the display 23 under control by the server 10. Although FIG. 1 shows an example of one information terminal 20, a plurality of information terminals may be connected to the server 10 via the network NT. The information terminal 20 includes a communication part 21, a processor 22, the display 23, and a manipulation part 24.

The communication part 21 includes a communication interface that connects the information terminal 20 to the network NT. The communication part 21 is configured to send, to the server 10, instruction signals respectively indicating various instructions which the manipulation part 24 receives from the user. The communication part 21 is configured to receive, from the server 10, display data to display various display screen images.

The processor 22 includes, for example, a central processing unit (CPU), and causes the display 23 to display a display screen image indicated by the display data received by the communication part 21.

The display 23 includes, for example, various display devices, e.g., liquid crystal displays or organic Electro-Luminescence (EL) displays, to display various display screen images under control by the processor 22.

The manipulation part 24 includes, for example, a keyboard, a touch screen, and a mouse, and is configured to receive various instructions input by the user.

The communication device 40 includes a mobile information terminal, e.g., a smartphone or a tablet computer, and connects the photographing device 30 to the network NT. The communication device 40 and the photographing device 30 are communicably connected to each other via a near field communication channel, such as the Bluetooth (registered trademark).

The photographing device 30 includes, for example, an omnidirectional camera, and captures an image at a predetermined frame rate. The omnidirectional camera is also referred to as a 360-degree camera, and can acquire an omnidirectional image at 360 degrees. The photographing device 30 is, for example, a portable photographing device carriable by a photographing person. The photographing person is, for example, a worker or a site supervisor on a construction site. The photographing device 30 may execute photographing in a state of being held in a hand of the photographing person or in a state of being attached to a body (e.g., the head) of the photographing person. The photographing device 30 may include a typical camera.

The photographing person moves on the construction site while photographing the construction site with the photographing device 30. The photographing person presses, at a photographing start spot, a photographing button of the photographing device 30 while making a photographing direction of the photographing device 30 agree with the north direction to start photographing, and presses the photographing button again to finish the photographing when reaching a photographing finish spot. When the photographing is finished, the photographing device 30 sends a series of images having been captured to the communication device 40.

Each image includes a photographing date and time. For instance, the photographing date and time is acquired by a timepiece included in the photographing device 30. Here, the photographing device 30 is configured to capture an image at a predetermined frame rate (e.g., ten frames per second), and therefore, a photographing spot is defined by a frame periodic unit. However, this leads to a huge amount of data, and thus, the photographing spot may be defined for a predetermined time period (e.g., one second, five seconds, or ten seconds).

The communication device 40 is configured to receive the images sent from the photographing device 30. The communication device 40 is further configured to display a design drawing for the construction site, and receive designation by the photographing person about a position corresponding to the photographing start spot and a position corresponding to the photographing finish spot in the design drawing.

The photographing start spot and the photographing finish spot are specified in response to input of instruction from the photographing person to designate the position corresponding to each spot in a design drawing screen image of a site displayed on a display of the communication device 40. A two-dimensional coordinate axis is defined in the design drawing screen image. Thus, each of the photographing start spot and the photographing finish spot is defined by a two-dimensional coordinate value. The server 10 uses each of the photographing start spot and the photographing finish spot to specify a position corresponding to each photographing spot and a photographing direction for each image.

The communication device 40 sends, to the server 10 via the network NT, photographing information including the captured images. The photographing information is generated at every execution of one photographing operation. The one photographing operation means a series of actions from start of photographing to finish of the photographing by a worker carrying the photographing device 30 on the construction site. A plurality of images is captured through the one photographing operation. The photographing information includes the captured images and meta information about each of the images. The meta information includes a photographing ID, a photographing date and time, and a design drawing ID. The photographing ID is an identifier to identify a photographing operation. The photographing date and time represents a photographing date and time for each image. The design drawing ID is an identifier to identify a design drawing for a predetermined space corresponding to an image.

The server 10 includes a processor 11, a memory 12, and a communication part 13. The processor 11 includes, for example, a central processing unit (CPU). The processor 11 includes an acquisition part 111, a selection receiving part 112, and a display control part 113. Each of the acquisition part 111, the selection receiving part 112, and the display control part 113 may come into effect, for example, when the processor 11 executes an information processing program, or may be established in the form of a dedicated hardware circuit, such as an application specific integrated circuit (ASIC). The information processing program may be recorded in a non-transitory computer-readable storage medium.

The communication part 13 includes a communication interface that connects the server 10 to the network NT. The communication part 13 is configured to receive the photographing information sent from the communication device 40. The communication part 13 is configured to receive, from the information terminal 20, instruction signals respectively indicating various instructions received from the user. The communication part 13 is configured to send, to the information terminal 20, display data to display various display screen images.

The memory 12 includes a non-volatile and rewritable storage device, such as a hard disk drive or a solid state drive. The memory 12 includes a design drawing information storage part 121 and an image information storage part 122.

The design drawing information storage part 121 stores design drawing information. The design drawing information includes image information indicating a design drawing for a predetermined space. The design drawing information is associated with a design drawing ID to identify the design drawing. The design drawing is an example of a bird’s-eye view. The design drawing represents a drawing of a design for a construction site, and may include a two-dimensional plan view, a blueprint, a map, or a perspective view of the construction site. The bird’s-eye view can be rephrased as an overhead view, that is, a view seen from above, or a view from a high position looking down.

The design drawing may include a three-dimensional simulation image of a predetermined space or a two-dimensional side view of the predetermined space. The three-dimensional simulation image indicates a three-dimensional computer aided design (CAD) image resulting from rendering three-dimensional CAD information, or a building information modeling (BIM) image resulting from rendering BIM information. For instance, in a case where the predetermined space is a construction site, an image resulting from rendering BIM information about a completed construction in a predetermined photographing direction is adopted as a three-dimensional simulation image. The two-dimensional plan view means a top view of the construction site seen from above, and the two-dimensional side view means a side view of the construction site seen from a side thereof.

The acquisition part 111 is configured to specify, by employing the Visual Simultaneous Localization and Mapping (SLAM) technique, a position corresponding to a photographing spot for each of the images from a photographing start spot, a photographing finish spot, and the images each included in the photographing information received by the communication part 13. Such a position corresponding to the photographing spot is expressed with a two-dimensional coordinate value in the design drawing. The acquisition part 111 further specifies a photographing direction for each of the images by employing the Visual SLAM technique. The photographing direction for each image is expressed with, for example, a three-dimensional polar coordinate vector.

The image information storage part 122 stores image information. The image information associates a plurality of captured images respectively captured at a plurality of photographing spots and meta information about each of the captured images with each other. The image information is generated at every receipt of the photographing information. The meta information includes a photographing ID, a photographing date and time, a photographing direction, a photographing spot, and a design drawing ID. The photographing direction represents a photographing direction in which the photographing device 30 has captured each image. The photographing spot represents positional information (a two-dimensional coordinate value) indicating the photographing spot for each image.

The communication part 13 is configured to receive an instruction to designate a photographing date and time from the information terminal 20. The manipulation part 24 of the information terminal 20 receives selection of the photographing date and time by the user, and the communication part 21 sends, to the server 10, an instruction to designate the photographing date and time selected by the user. The instruction to designate the photographing date and time contains a photographing ID.

The acquisition part 111 acquires, from the design drawing information storage part 121, a design drawing corresponding to the design drawing ID contained in the instruction to display the design drawing received by the communication part 13. Moreover, the acquisition part 111 acquires, from the image information storage part 122, a plurality of photographing spots each corresponding to the photographing ID contained in the instruction to designate the photographing date and time received by the communication part 13.

The display control part 113 is configured to cause the display 23 of the information terminal 20 to display a design drawing corresponding to the predetermined space. The display control part 113 causes the display 23 of the information terminal 20 to display the design drawing acquired by the acquisition part 111. The display control part 113 is configured to send display data for the design drawing to the information terminal 20 via the communication part 13. The communication part 21 of the information terminal 20 receives the display data sent from the server 10. The display 23 displays the design drawing received by the communication part 21.

The display control part 113 is configured to display, in the design drawing, a plurality of photographing spot icons respectively indicating a plurality of photographing spots acquired by the acquisition part 111. The photographing spot icons are respectively associated with a plurality of images captured at the photographing spots.

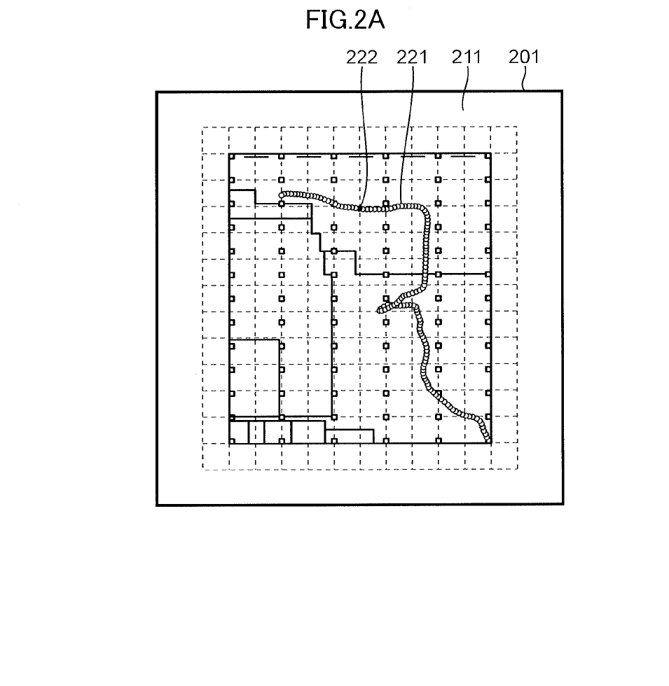

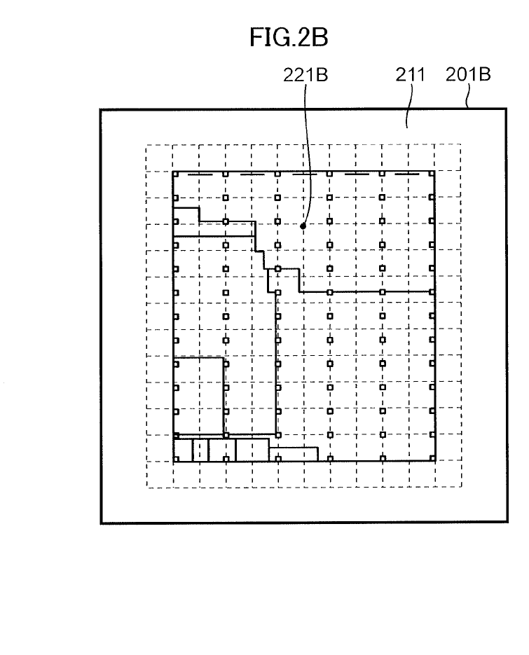

FIG. 2A illustrates an example design drawing screen image 201 in which a plurality of photographing spot icons 221 is mapped in the embodiment. The design drawing screen image 201 shows a design drawing 211 for a predetermined space. In the design drawing screen image 201, the photographing spot icons 221 are superimposed and displayed.

Each photographing spot icon 221 indicates a photographing spot. The photographing spot icon 221 is associated with an image captured at the photographing spot. In this example, the photographing spot icon 221 includes an image having a circular shape with a predetermined dimension. The photographing spot icons 221 displayed here respectively correspond to a plurality of photographing spots belonging to one certain photographing operation. A route from the photographing spot icon 221 at one end (the photographing spot icon located at a lower right position in FIG. 2A) to the photographing spot icon 221 at another end (the photographing spot icon located at an upper left position in FIG. 2A) shows a trace followed by the photographing person in the photographing operation.

The photographing device 30 captures an image at a predetermined frame rate. In this configuration, the number of images is expressed with “frame rate (fps) * photographing time (sec.)”. FIG. 2A shows the photographing spot icons 221 displayed in an overlapping manner along the trace followed by the photographing person.

The manipulation part 24 receives selection of one photographing spot icon by the user from among the photographing spot icons 221. The user has a mouse pointer over the one photographing spot icon among the photographing spot icons 221, and clicks a left button of the mouse. Alternatively, the user touches the one photographing spot icon among the photographing spot icons 221. In the example in FIG. 2A, one photographing spot icon 222 is selected from among the photographing spot icons 221.

When the one photographing spot icon is selected from among the photographing spot icons 221, the display control part 113 reads out, from the image information storage part 122, a captured image corresponding to the selected one photographing spot icon, and causes the display 23 to display the read out captured image.

Although FIG. 2A shows the photographing spot icons 221 superposed and displayed, one photographing spot icon showing only a point selected in advance and being necessary to acquire data may be displayed.

FIG. 2B illustrates an example design drawing screen image 201B in which one photographing spot icon 221B is mapped in the embodiment. The design drawing screen image 201B shows a design drawing 211 for a predetermined space. In the design drawing screen image 201B, the one photographing spot icon 221B is superimposed and displayed. The one photographing spot icon 221B displayed here corresponds to one photographing spot.

The manipulation part 24 receives selection of the one photographing spot icon 221B by the user. The user has the mouse pointer over the one photographing spot icon 221B, and clicks the left button of the mouse. Alternatively, the user touches the one photographing spot icon 221B.

When the one photographing spot icon 221B is selected, the display control part 113 reads out, from the image information storage part 122, a captured image corresponding to the selected one photographing spot icon 221B, and causes the display 23 to display the read out captured image.

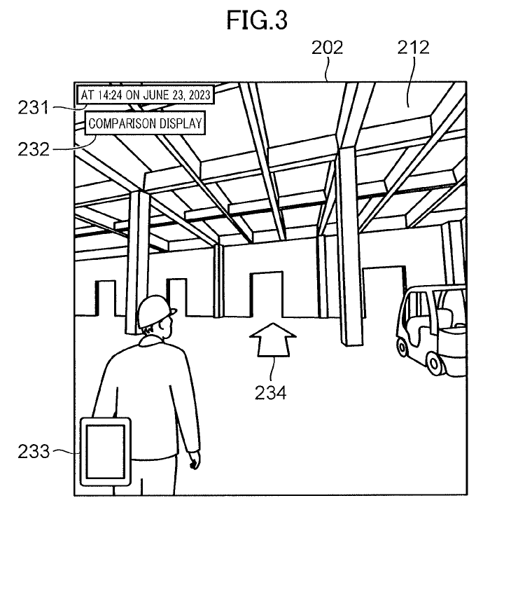

FIG. 3 illustrates an example captured image screen image 202 to be displayed on the display 23 when the photographing spot icon 222 is selected in the embodiment.

The captured image screen image 202 shows a captured image 212 captured at a photographing spot corresponding to the selected photographing spot icon 222. The display control part 113 is configured to display one captured image among a plurality of captured images having been continuously captured. Here, the display control part 113 is configured to cause the display 23 to display a captured image having a rectangular shape cut out from an omnidirectional image in relation to a sightline direction. The captured image screen image 202 has a date field 231, a comparison display button 232, a design drawing display field 233, and a walkthrough instruction button 234.

The date field 231 shows a photographing date and time for the captured image 212. The comparison display button 232 is a button to display the captured image 212 and the design drawing 211 for comparison with each other. The design drawing display field 233 shows the design drawing screen image 201, which is illustrated in FIG. 2A, in a smaller size.

The display control part 113 is configured to display the walkthrough instruction button 234 for switching from one captured image being displayed to a captured image captured before the one captured image or to a captured image captured after the one captured image. The walkthrough instruction button 234 is an example of a switch icon.

The walkthrough instruction button 234 is a button for switching from the captured image 212 to a subsequent captured image having a photographing date and time later than the photographing date and time for the captured image 212. The user may switch the captured image 212 to a previous captured image having a photographing date and time earlier than the photographing date and time for the captured image 212. In this case, the display control part 113 may cause the display 23 to display an opposite walkthrough instruction button 234 facing in a direction opposite to a direction in which the walkthrough instruction button 234 faces in response to an instruction from the user, or display one previous captured image in response to input of an instruction to select the opposite walkthrough instruction button 234.

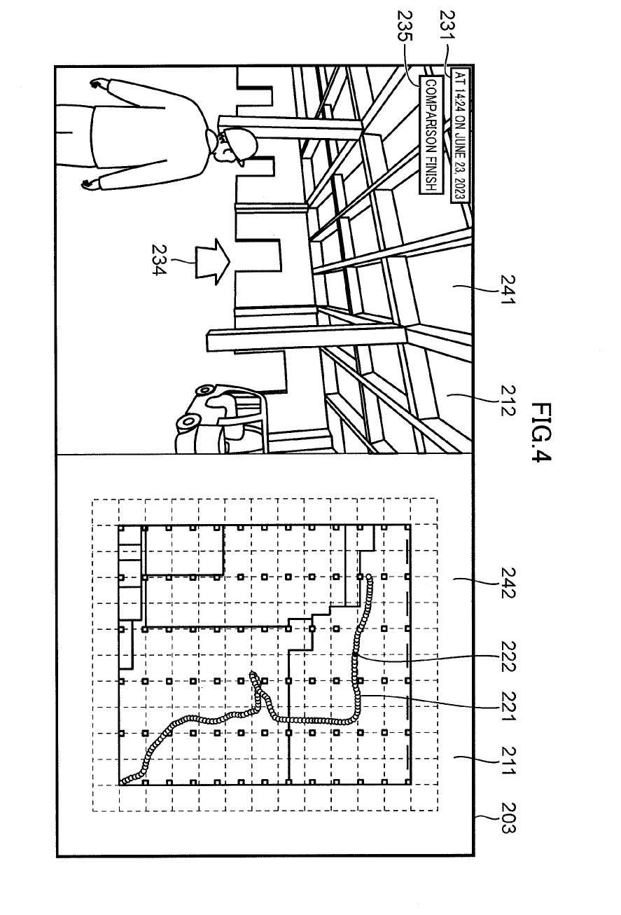

The user presses the comparison display button 232 to cause the display 23 to display the captured image 212 and the design drawing 211 adjacent to each other. When the comparison display button 232 is pressed, the display 23 displays a comparison display screen image 203 illustrated in FIG. 4.

FIG. 4 illustrates the comparison display screen image 203 to display the captured image and the design drawing in the embodiment. The display 23 displays the comparison display screen image 203 in response to receipt of a selection instruction of the comparison display button 232.

The display control part 113 is configured to cause the display 23 of the information terminal 20 to display the captured image 212 obtained by photographing the predetermined space and the design drawing (bird’s-eye view) 211 corresponding to the predetermined space. Specifically, the manipulation part 24 of the information terminal 20 is configured to receive a comparison display instruction to display the captured image and the design drawing adjacent to each other, and the communication part 21 sends the comparison display instruction to the server 10. The communication part 13 is configured to receive, from the information terminal 20, the comparison display instruction to display the captured image and the design drawing adjacent to each other. When the communication part 13 receives the comparison display instruction to display the captured image and the design drawing adjacent to each other, the display control part 113 displays the captured image 212 and the design drawing 211 adjacent to each other.

The comparison display screen image 203 includes a first region 241 and a second region 242 resulting from dividing the image into the two left and right regions. The first region 241 shows the captured image 212, and the second region 242 shows the design drawing 211.

The comparison display screen image 203 has the date field 231, the walkthrough instruction button 234, and a comparison finish button 235.

The user presses the comparison finish button 235 to finish the displaying of the captured image 212 and the design drawing 211. When the comparison finish button 235 is pressed, the display 23 finishes the displaying of the comparison display screen image 203 illustrated in FIG. 4.

The display control part 113 restores the captured image screen image 202 from the comparison display screen image 203 for screen image displaying on the display 23 in response to the pressing of the comparison finish button 235. Specifically, the manipulation part 24 of the information terminal 20 is configured to receive a comparison finish instruction to finish the displaying of the captured image and the design drawing, and the communication part 21 is configured to send the comparison finish instruction to the server 10. The communication part 13 is configured to receive, from the information terminal 20, the comparison finish instruction to finish the displaying of the captured image and the design drawing. When the communication part 13 receives the comparison finish instruction to finish the displaying of the captured image and the design drawing, the display control part 113 displays only the captured image 212.

The captured image includes an omnidirectional image. Therefore, the display control part 113 may receive a manipulation to change a sightline direction in the captured image 212. The display control part 113 is configured to change the sightline direction in the captured image 212 depending on a manipulation amount and a manipulation direction in response to input of a manipulation to change the sightline direction in the captured image 212 by the user through the manipulation part 24. For instance, the user has the mouse pointer over the captured image 212 and shifts the mouse while clicking the left button of the mouse, that is, performs a dragging manipulation. Alternatively, the user puts a finger thereof on the captured image 212 and shifts the finger while keeping the finger touching the image, that is, performs a swiping manipulation. As a result, the sightline direction in the captured image 212 is changed.

In a case where the sightline direction in the captured image 212 is changed, the display control part 113 is configured to rotate the design drawing 211 so that the sightline direction agrees with, in the design drawing 211, a direction toward an upper side of the design drawing 211. The rotation consequently makes the sightline direction in the captured image 212 agree with the direction toward the upper side of the design drawing 211, and thus allows the user to easily recognize, in the design drawing 211, the sightline direction.

In the embodiment, the display control part 113 may be configured to display, in the design drawing 211, an arrow icon indicating the sightline direction in the captured image 212. In a case where the sightline direction in the captured image 212 is changed, the display control part 113 may rotate the arrow icon so that the sightline direction agrees with, in the design drawing 211, a direction indicated by the arrow icon. In this case, the display control part 113 rotates the arrow icon without rotating the design drawing 211. The rotation consequently makes the sightline direction in the captured image 212 agree with the direction indicated by the arrow icon displayed in the design drawing 211, and thus allows the user to easily recognize, in the design drawing 211, the sightline direction.

The display control part 113 may receive a manipulation to increase or reduce a size of the captured image 212. The display control part 113 increases or reduces the size of the captured image 212 depending on a manipulation amount in response to input of such a manipulation to increase or reduce the size of the captured image 212 by the user through the manipulation part 24. For instance, the user presses a size increase button or a size reduction button displayed in the captured image 212. Alternatively, the user puts two fingers thereof on the captured image 212 and moves the fingers apart from each other, that is, perform a pinch-out manipulation, or close to each other, that is, performs a pinch-in manipulation, while keeping the fingers touching the image. This results in increasing or reducing the size of the captured image 212.

The selection receiving part 112 is configured to receive selection of two certain points in a design drawing or a captured image by the user.

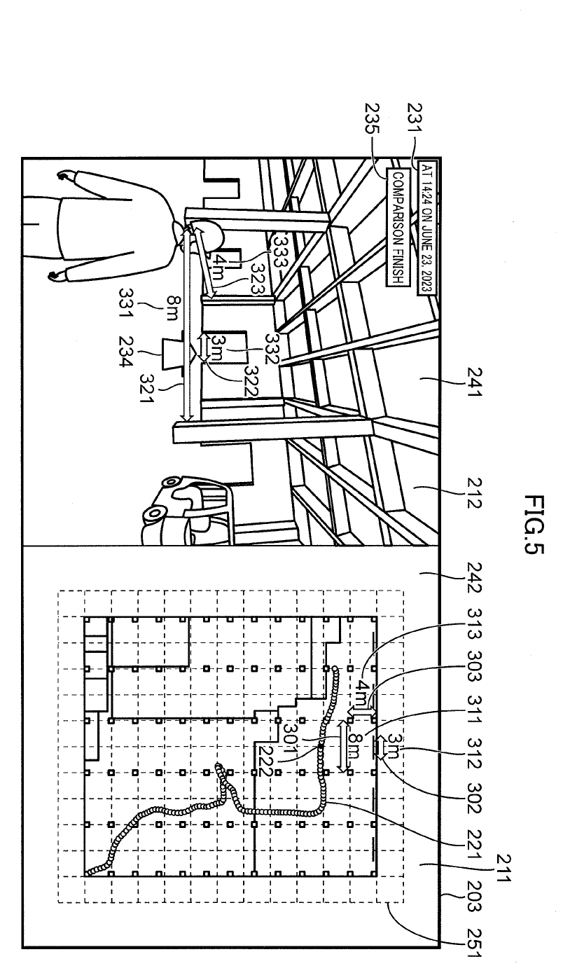

FIG. 5 illustrates a comparison display screen image 203 to display a distance between two points in the captured image.

In the embodiment, the selection receiving part 112 is configured to receive selection of two certain points in the design drawing 211 by the user. The user designates two points defining an interval corresponding to a distance that the user wishes to know in the design drawing 211 through the manipulation part 24. The user shifts the mouse pointer to each of a start point position and a finish point position defining an interval corresponding to a distance to be measured in the design drawing 211, and clicks the left button of the mouse. Alternatively, the user may shift the mouse pointer to the start point position of the interval corresponding to the distance to be measured in the design drawing 211 and click the left button of the mouse, and then shift the mouse pointer to the finish point position while clicking the left button of the mouse and leave the left button of the mouse there.

The display control part 113 is configured to display, in the design drawing 211, an arrow icon 301 connecting the two certain points received by the selection receiving part 112 to each other.

The display control part 113 is configured to display, in the captured image 212, a distance between two points in the captured image 212 corresponding to the two certain points selected in the design drawing 211. The display control part 113 is configured to calculate a distance between the two certain points selected in the design drawing 211, and display, in the captured image 212, the calculated distance as the distance between the two points in the captured image 212. The design drawing 211 includes grid lines 251 to show an actual dimension of a predetermined space. Therefore, the display control part 113 can accurately calculate the distance between the two certain points selected in the design drawing 211.

The design drawing 211 includes a two-dimensional plan view of the predetermined space. The selection receiving part 112 is configured to receive selection of the two certain points in a horizontal direction in the two-dimensional plan view. The display control part 113 is configured to calculate the distance between the two certain points in the horizontal direction selected in the design drawing 211, and display, in the captured image 212, the calculated distance as the distance between the two points in the horizontal direction in the captured image 212. Here, the horizontal direction includes both the X direction and the Y direction. Regarding the selection of two points, the selection can be canceled due to, for example, reselection.

The display control part 113 is configured to extract a feature point in the captured image 212, and recognize a structure, such as a pillar, a wall, and a door, shown in the captured image 212. The display control part 113 is further configured to decide, on the basis of a position of the structure shown in the captured image 212 and a position of the structure shown in the design drawing 211, a start point position and a finish point position in the captured image 212 corresponding to a start point position and a finish point position in the design drawing 211

The display control part 113 is configured to display a distance 311 between two points in the vicinity of the arrow icon 301. The selection receiving part 112 may receive selection of two points defining each of a plurality of intervals, and the display control part 113 may calculate a distance between the two points defining each of the intervals.

In FIG. 5, a plurality of arrow icons 301, 302, and 303 respectively corresponding to a plurality of intervals is displayed in the design drawing 211, and a plurality of distances 311, 312, and 313 is displayed in the vicinity of the arrow icons 301, 302, and 303. The arrow icons 301, 302, and 303 may be displayed differently from one another, or may be displayed in different colors from one another. The distances 311, 312, and 313 may be displayed differently from one another, or may be displayed in different colors from one another. For instance, the arrow icon 301 and the distance 311 may be displayed in red, the arrow icon 302 and the distance 312 may be displayed in blue, and the arrow icon 303 and the distance 313 may be displayed in green.

Although the display control part 113 is configured to display the distance 311 between the two points in the design drawing 211, the present disclosure is not particularly limited thereto. The display control part 113 may be configured to display only the arrow icon 301 connecting the two points to each other in the design drawing 211 without displaying the distance 311 between the two points in the design drawing 211.

The display control part 113 is further configured to display, in the captured image 212, an arrow icon 321 connecting two points in the captured image 212 corresponding to two certain points in the design drawing 211 as received by the selection receiving part 112, and display a distance 331 between the two points in the vicinity of the arrow icon 321. In a case where the selection receiving part 112 receives selection of two points defining each of a plurality of intervals, the display control part 113 may display, in the captured image 212, a distance of each of the intervals in the captured image 212 corresponding to each of a plurality of intervals selected in the design drawing 211.

In FIG. 5, a plurality of arrow icons 321, 322, and 323 respectively corresponding to the intervals is displayed in the captured image 212, and a plurality of distances 331, 332, and 333 is displayed in the vicinity of the arrow icons 321, 322, and 323. The arrow icons 321, 322, and 323 may be displayed differently from one another, or may be displayed in different colors from one another. The distances 331, 332, and 333 may be displayed differently from one another, or may be displayed in different colors from one another. For instance, the arrow icon 321 and the distance 331 may be displayed in red, the arrow icon 322 and the distance 332 may be displayed in blue, and the arrow icon 323 and the distance 333 may be displayed in green.

In a case where the walkthrough instruction button 234, i.e., the switch icon, is selected, the display control part 113 may switch from one captured image to a captured image captured before the one captured image or to a captured image captured after the one captured image, and display a distance in the captured image resulting from the switching.

Although each of the arrow icons 301, 302, 303, 321, 322, and 323 has arrow heads respectively at the opposite ends thereof, the present disclosure is not limited thereto. Each of the arrow icons 301, 302, 303, 321, 322, and 323 may not have such arrow heads at the opposite ends, resulting in a straight linear shape.

Next, a distance displaying process by the server 10 in the embodiment will be described.

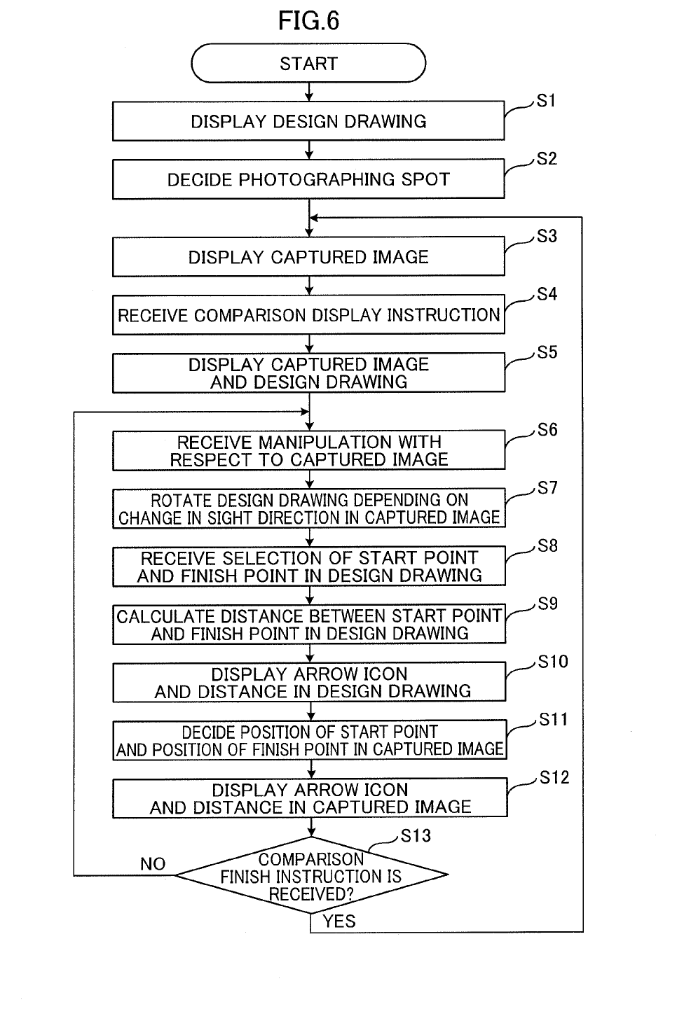

FIG. 6 is a flowchart showing an example of the distance displaying process by the server 10 in the embodiment.

First, in step S1, the display control part 113 causes the display 23 of the information terminal 20 to display a design drawing corresponding to a predetermined space.

Here, the communication part 13 receives an instruction to display the design drawing from the information terminal 20. In this case, the display 23 of the information terminal 20 displays a menu screen image for design drawing selection, and the manipulation part 24 receives an instruction from the user to select one design drawing from the menu screen image. The instruction input in this manner is sent to the server 10 via the network NT and received by the communication part 13. The instruction to display the design drawing contains a design drawing ID. The acquisition part 111 acquires, from design drawing information stored in the design drawing information storage part 121, a design drawing corresponding to the design drawing ID contained in the instruction to display the design drawing received by the communication part 13. The display control part 113 sends display data for the design drawing to the information terminal 20 via the communication part 13, and then causes the display 23 of the information terminal 20 to display the design drawing.

The design drawing includes a plurality of photographing spot icons. The manipulation part 24 may receive an instruction from the user to select a desired photographing date and time. The acquisition part 111 may acquire, from image information stored in the image information storage part 122, a plurality of photographing spots related to the selected photographing date and time. The display control part 113 may display, in the design drawing, a plurality of photographing spot icons respectively indicating the acquired photographing spots.

Subsequently, in step S2, the display control part 113 decides a photographing spot from the photographing spots in accordance with the instruction received by the communication part 13. As illustrated in FIG. 2A, in response to receipt of such a selection instruction for the photographing spot icon, the information terminal 20 sends the selection instruction to the server 10. The selection instruction contains a photographing ID and a photographing date and time. When the communication part 13 receives the selection instruction, the display control part 113 detects the selection of the photographing spot icon. The display control part 113 decides the photographing spot on the basis of each of the photographing ID and the photographing date and time, as a key, contained in the selection instruction received by the communication part 13.

Next, in step S3, the display control part 113 displays a captured image captured at the decided photographing spot. Specifically, the display control part 113 sends display data for the captured image to the information terminal 20 via the communication part 13. In the information terminal 20, the processor 22 causes the display 23 to display the display data received by the communication part 21. In this way, the display 23 displays the captured image screen image 202 illustrated in FIG. 3.

Then, in step S4, the communication part 13 receives, from the information terminal 20, a comparison display instruction to display the captured image and the design drawing adjacent to each other. The comparison display instruction is input in response to pressing of the comparison display button 232 displayed in the captured image screen image 202. The processor 22 sends the comparison display instruction to the server 10 via the communication part 21.

Next, in step S5, the display control part 113 displays the captured image and the design drawing adjacent to each other. Specifically, the display control part 113 sends display data for each of the captured image and the design drawing to the information terminal 20 via the communication part 13. In the information terminal 20, the processor 22 causes the display 23 to display the display data received by the communication part 21. In this way, the display 23 displays the comparison display screen image 203 illustrated in FIG. 4.

Subsequently, in step S6, the display control part 113 receives a manipulation with respect to the captured image. Here, the display control part 113 receives a manipulation to change a sightline direction in the captured image, or receives a manipulation to increase or reduce a size of the captured image. In a case where the manipulation to change the sightline direction in the captured image is performed, the display control part 113 causes the display 23 to display, as a captured image, an image having a rectangular shape cut out from an omnidirectional image in relation to the changed sightline direction. Alternatively, in a case where the manipulation to increase or reduce the size of the captured image is performed, the display control part 113 increases or reduces the size of the captured image being currently displayed.

Then, in step S7, the display control part 113 rotates the design drawing depending on the change in the sightline direction in the captured image. Here, in a case where the sightline direction in the captured image is changed, the display control part 113 rotates the design drawing to make the sightline direction agree with, in the design drawing, a direction toward an upper side of the design drawing.

Next, in step S8, the selection receiving part 112 receives selection of a start point and a finish point in the design drawing by the user. The manipulation part 24 of the information terminal 20 receives, in the design drawing, input by the user about a start point and a finish point defining an interval corresponding to a distance that the user wishes to measure. The processor 22 sends, to the server 10 via the communication part 21, positional information indicating a coordinate of each of the start point and the finish point input in the design drawing. The positional information sent from the information terminal 20 is received by the communication part 13 and input into the display control part 113. In this way, the display control part 113 receives the selection of each of the start point and the finish point in the design drawing.

Subsequently, in step S9, the display control part 113 calculates a distance between the start point and the finish point in the design drawing.

Then, in step S10, the display control part 113 displays an arrow icon connecting the start point and the finish point to each other in the design drawing, and displays a distance between the start point and the finish point in the vicinity of the arrow icon.

Then, in step S11, the display control part 113 decides a position of a start point and a position of a finish point in the captured image respectively corresponding to a position of the start point and a position of the finish point in the design drawing. For instance, the display control part 113 extracts a feature point in the captured image and recognizes a pillar and a door in the captured image. The display control part 113 further acquires, in the design drawing, a photographing spot and a sightline direction concerning the captured image, and recognizes, from the photographing spot shown in the design drawing, the pillar and the door existing in the sightline direction. Furthermore, the display control part 113 decides the position of the start point and the position of the finish point in the captured image respectively corresponding to the position of the start point and the position of the finish point in the design drawing by using a position of each of the pillar and the door recognized in the captured image, a position of each of the pillar and the door recognized in the design drawing, and the position of the start point and the position of the finish point in the design drawing.

Next, in step S12, the display control part 113 displays an arrow icon connecting the start point and the finish point to each other in the captured image, and displays a distance between the start point and the finish point in the vicinity of the arrow icon. In this way, the display 23 displays the comparison display screen image 203 illustrated in FIG. 5.

Subsequently, in step S13, the communication part 13 determines whether a comparison finish instruction to finish the displaying of the captured image and the design drawing is received from the information terminal 20. The comparison finish instruction is input in response to pressing of the comparison finish button 235 displayed in the comparison display screen image 203. The processor 22 sends the comparison finish instruction to the server 10 via the communication part 21.

When it is determined that the comparison finish instruction is received (YES in step S13), the process returns to step S3, and the display control part 113 displays only the captured image. Alternatively, when it is determined that the comparison finish instruction is received, the process may return to step S1, and the display control part 113 may display only the design drawing.

In contrast, when it is determined that the comparison finish instruction is not received (NO in step S13), the process returns to step S6, and the display control part 113 receives a manipulation with respect to the captured image.

Conclusively, this configuration includes displaying, in a captured image, a distance between two points in the captured image corresponding to two certain points selected in a design drawing. This configuration thus enables presentation of a distance between two desired points in a captured image to a user with high accuracy. The configuration further enables presentation of the distance in each of the X-direction and the Y-direction including a depth (Y-direction). Moreover, the configuration that includes the presentation of the distance between the two desired distance in the captured image to the user achieves a reduction in the number of processing steps required by a computer for confirmation of the distance between the two points, and hence achieves a reduction in the burden on the computer. Furthermore, the configuration includes calculating the distance between the two certain points in the design drawing, and thus enables calculation of an exact distance. The configuration further includes displaying, in the captured image, the calculated distance as the distance between the two points in the captured image, and thus enables presentation of an exact distance between two desired points in the captured image to the user. As described above, the distance may be displayed in both the design drawing and the captured image, may be displayed in one of the design drawing and the captured image, or may be displayed in another manner.

Although the display control part 113 is configured to display, in the design drawing, a plurality of photographing spot icons respectively indicating a plurality of photographing spots having been continuously captured in the embodiment, the present disclosure is not particularly limited thereto. The display control part 113 may display, in the design drawing, one photographing spot icon indicating one photographing spot at which photographing has been individually executed. The display control part 113 may display, in the design drawing, a plurality of photographing spot icons respectively indicating a plurality of photographing spots at which photographing has been individually executed.

In the embodiment, the design drawing may include a three-dimensional simulation image of a predetermined space or a two-dimensional side view of the predetermined space. In this configuration, the selection receiving part 112 may be configured to receive selection of two certain points in a vertical direction in the three-dimensional simulation image or the two-dimensional side view. The display control part 113 may calculate a distance between the two points in the vertical direction selected in the design drawing, and display, in the captured image, the calculated distance as a distance between two points in the vertical direction in the captured image.

First modification

In the embodiment, selection of two certain points in a design drawing (bird’s-eye view) is received, and a distance between two points in a captured image corresponding to the two certain points selected in the design drawing (bird’s-eye view) is displayed in the captured image. In contrast, in a first modification of the embodiment, selection of two certain points in a captured image is received, and a distance between two points in a design drawing (bird’s-eye view) corresponding to the two certain points selected in the captured image is displayed in the design drawing (bird’s-eye view).

In the first modification of the embodiment, constituent elements which are the same as those in the embodiment are given the same reference numerals and signs, and thus, the descriptions therefor will be omitted. Besides, the block diagram shown in FIG. 1 is used as a block diagram for the first modification of the embodiment.

In the first modification of the embodiment, a selection receiving part 112 receives selection of two certain points in a captured image 212 by a user. The user designates such two points defining an interval corresponding to a distance that the user wishes to know in the captured image 212 through a manipulation part 24. The user shifts a mouse pointer to each of a start point position and a finish point position defining an interval corresponding to a distance to be measured in the captured image 212, and clicks the left button of the mouse. Alternatively, the user may shift the mouse pointer to the start point position of the interval corresponding to the distance to be measured in the captured image 212 and click the left button of the mouse, and then shift the mouse pointer to the finish point position while clicking the left button of the mouse and leave the left button of the mouse there.

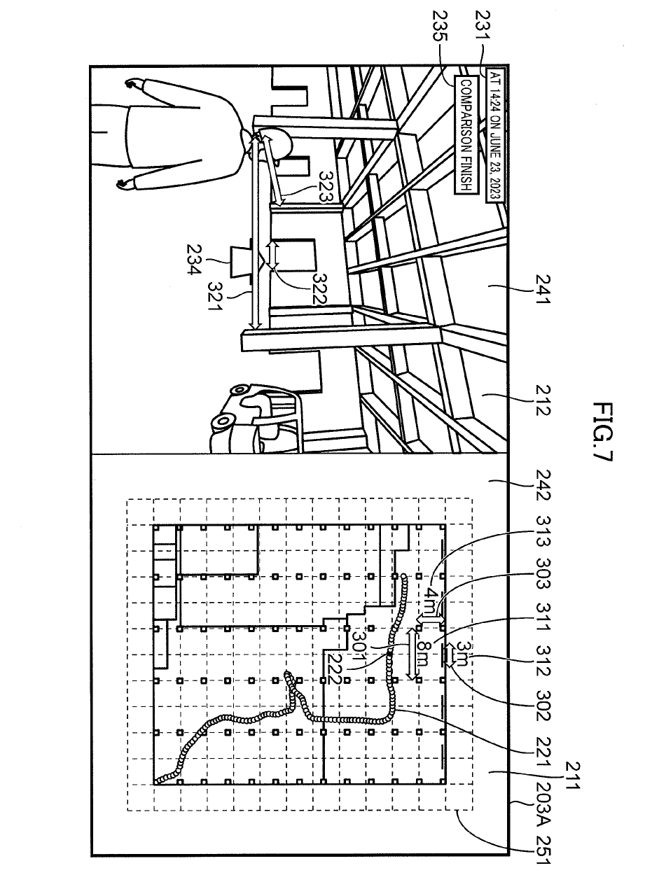

FIG. 7 illustrates a comparison display screen image 203A to display a distance between two points in a captured image in the first modification of the embodiment.

The display control part 113 is configured to display, in a design drawing 211 (bird’s-eye view), a distance between two points in the design drawing 211 (bird’s-eye view) corresponding to two certain points selected in the captured image 212. The display control part 113 is configured to calculate a distance between the two points in the design drawing 211 (bird’s-eye view) corresponding to the two certain points selected in the captured image 212, and display the calculated distance in the design drawing 211 (bird’s-eye view).

In FIG. 7, a plurality of arrow icons 321, 322, and 323 respectively corresponding to a plurality of intervals is displayed in the captured image 212. The arrow icons 321, 322, and 323 may be displayed differently from one another, or may be displayed in different colors from one another. For instance, the arrow icon 321 may be displayed in red, the arrow icon 322 may be displayed in blue, and the arrow icon 323 may be displayed in green.

In FIG. 7, a plurality of arrow icons 301, 302, and 303 respectively corresponding to the intervals is displayed in the design drawing 211, and a plurality of distances 311, 312, and 313 is displayed in the vicinity of the arrow icons 301, 302, and 303. The arrow icons 301, 302, and 303 may be displayed differently from one another, or may be displayed in different colors from one another. The distances 311, 312, and 313 may be displayed differently from one another, or may be displayed in different colors from one another. For instance, the arrow icon 301 and the distance 311 may be displayed in red, the arrow icon 302 and the distance 312 may be displayed in blue, and the arrow icon 303 and the distance 313 may be displayed in green.

In the first modification of the embodiment, the display control part 113 displays the arrow icons 321, 322, and 323 each connecting a start point and a finish point to each other in the captured image 212, but avoids displaying a distance in the vicinity of each of the arrow icons 321, 322, and 323 in the captured image 212.

Next, a distance displaying process by a server 10 in the first modification of the embodiment will be described.

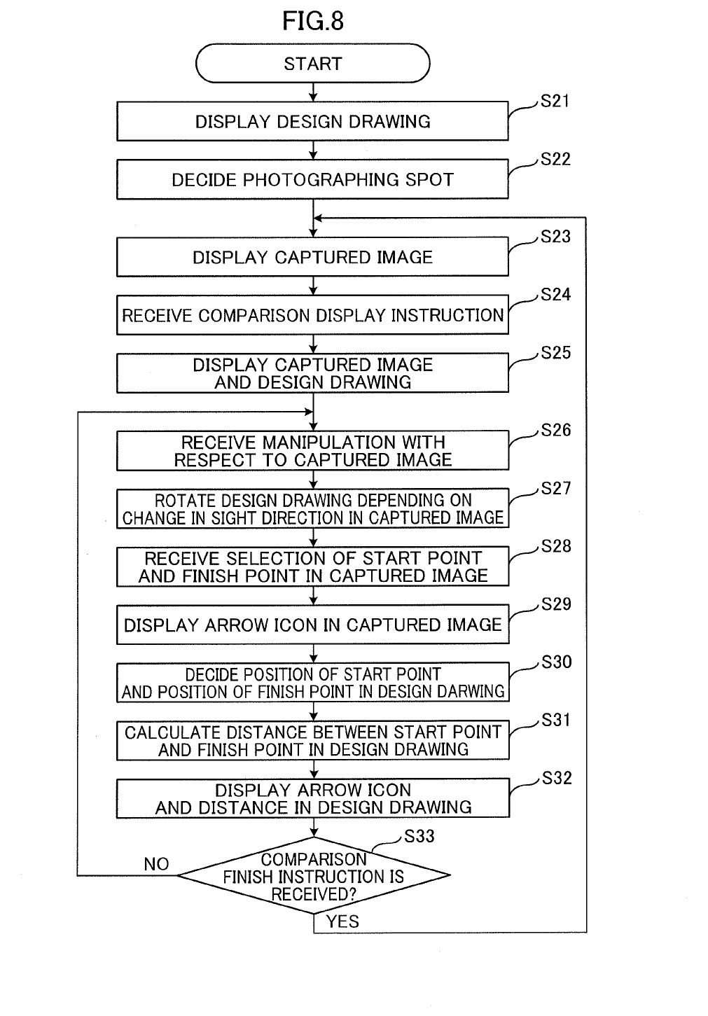

FIG. 8 is a flowchart showing an example of the distance displaying process by the server 10 in the first modification of the embodiment.

Here, step S21 to step S27 are the same as steps S1 to Step S7 in FIG. 6, and thus, the descriptions therefor will be omitted.

Subsequently, in step S28, the selection receiving part 112 receives selection of a start point and a finish point in a captured image by a user. The manipulation part 24 of an information terminal 20 receives input by the user about a start point and a finish point defining an interval corresponding to a distance that the user wishes to measure in the captured image. A processor 22 sends, to the server 10 via a communication part 21, positional information indicating a coordinate of each of the input start point and the input finish point in the input captured image. The positional information sent from the information terminal 20 is received by a communication part 13 and input into a display control part 113. In this way, the display control part 113 receives the selection of each of the start point and the finish point in the captured image.

Then, in step S29, the display control part 113 displays an arrow icon connecting the start point and the finish point to each other in the captured image.

Next, in step S30, the display control part 113 decides a position of a start point and a position of a finish point in the design drawing respectively corresponding to a position of the start point and a position of the finish point in the captured image. For instance, the display control part 113 extracts a feature point in the captured image and recognizes a pillar and a door in the captured image. The display control part 113 further acquires, in the design drawing, a photographing spot and a sightline direction concerning the captured image, and recognizes, from the photographing spot shown in the design drawing, the pillar and the door existing in the sightline direction. Furthermore, the display control part 113 decides the position of the start point and the position of the finish point in the design drawing respectively corresponding to the position of the start point and the position of the finish point in the captured image by using a position of each of the pillar and the door recognized in the captured image, a position of each of the pillar and the door recognized in the design drawing, and the position of the start point and the position of the finish point in the captured image.

Subsequently, in step S31, the display control part 113 calculates a distance between the start point and the finish point in the design drawing.

Then, in step S32, the display control part 113 displays an arrow icon connecting the start point and the finish point to each other in the design drawing, and displays the distance between the start point and the finish point in the vicinity of the arrow icon. In this way, the display 23 displays the comparison display screen image 203A illustrated in FIG. 7.

Step S33 is the same as step S13 in FIG. 6, and thus, the descriptions therefor will be omitted.

Conclusively, this configuration includes displaying, in a design drawing, a distance between two points in the design drawing corresponding to two certain points selected in a captured image. This configuration thus enables presentation of a distance between two desired points in a captured image to a user with high accuracy. The configuration further enables presentation of the distance in each of the X-direction and the Y-direction including a depth (Y-direction). Moreover, this configuration includes calculating the distance between the two points in the design drawing corresponding to the two certain points selected in the captured image, and thus enables calculation of an exact distance. The configuration further includes displaying the calculated distance in the design drawing, and thus enables presentation of an exact distance between two desired points in the captured image to the user. The distance may be displayed in both the design drawing and the captured image, may be displayed in one of the design drawing and the captured image, or may be displayed in another manner.

Second modification

In the embodiment, selection of two certain points in a design drawing (bird’s-eye view) is received, and a distance between two points in a captured image corresponding to the two certain points selected in the design drawing (bird’s-eye view) is displayed in the captured image. In contrast, in a second modification of the embodiment, selection of two certain points in a captured image is received, and a distance between the two certain points selected in the captured image is displayed in the captured image.

In the second modification of the embodiment, constituent elements which are the same as those in the embodiment are given the same reference numerals and signs, and thus, the descriptions therefor will be omitted. Besides, the block diagram shown in FIG. 1 is used as a block diagram for the second modification of the embodiment.

In the second modification of the embodiment, a selection receiving part 112 receives selection of two certain points in a captured image 212 by a user. The user designates such two points defining an interval corresponding to a distance that the user wishes to know in the captured image 212 through a manipulation part 24. The user shifts a mouse pointer to each of a start point position and a finish point position defining an interval corresponding to a distance to be measured in the captured image 212, and clicks the left button of the mouse. Alternatively, the user may shift the mouse pointer to the start point position of the interval corresponding to the distance to be measured in the captured image 212 and click the left button of the mouse, and then shift the mouse pointer to the finish point position while clicking the left button of the mouse and leave the left button of the mouse there.

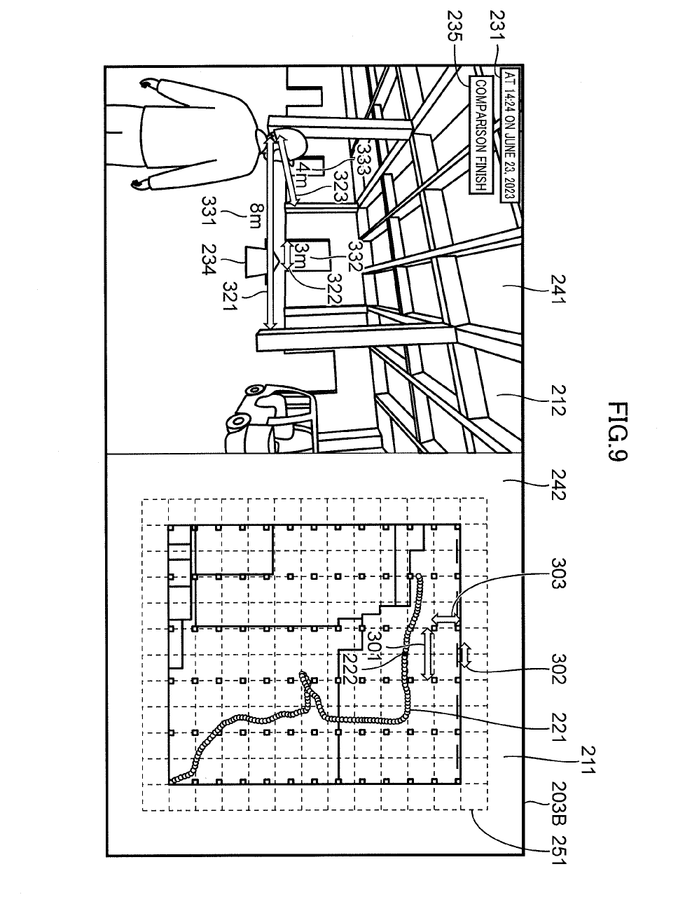

FIG. 9 illustrates a comparison display screen image 203B to display a distance between two points in a captured image in the second modification of the embodiment.

A display control part 113 is configured to display, in the captured image 212, a distance between the two certain points selected in the captured image 212. The display control part 113 is configured to calculate a distance between two points in a design drawing 211 (bird’s-eye view) corresponding to the two certain points selected in the captured image 212, and display the calculated distance in the captured image 212.

In FIG. 9, a plurality of arrow icons 321, 322, and 323 respectively corresponding to a plurality of intervals is displayed in the captured image 212, and a plurality of distances 331, 332, and 333 is displayed in the vicinity of the arrow icons 321, 322, and 323. The arrow icons 321, 322, and 323 may be displayed differently from one another, or may be displayed in different colors from one another. The distances 331, 332, and 333 may be displayed differently from one another, or may be displayed in different colors from one another. For instance, the arrow icon 321 and the distance 331 may be displayed in red, the arrow icon 322 and the distance 332 may be displayed in blue, and the arrow icon 323 and the distance 333 may be displayed in green.

In FIG. 9, a plurality of arrow icons 301, 302, and 303 respectively corresponding to a plurality of intervals is displayed in the design drawing 211. The arrow icons 301, 302, and 303 may be displayed differently from one another, or may be displayed in different colors from one another. For instance, the arrow icon 301 may be displayed in red, the arrow icon 302 may be displayed in blue, and the arrow icon 303 may be displayed in green.

In the second modification of the embodiment, the display control part 113 displays, in the design drawing 211, the arrow icons 301, 302, and 303 each connecting a start point and a finish point to each other, but avoids displaying a distance in the vicinity of each of the arrow icons 301, 302, and 303 in the design drawing 211.

Next, a distance displaying process by a server 10 in the second modification of the embodiment will be described.

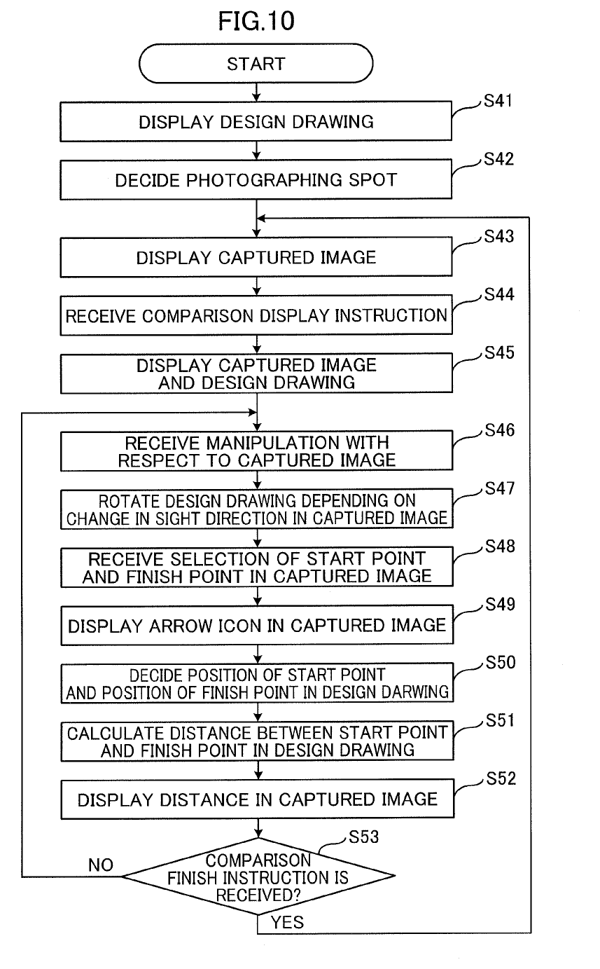

FIG. 10 is a flowchart showing an example of the distance displaying process by the server 10 in the second modification of the embodiment.

Here, step S41 to step S47 are the same as step S1 to step S7 in FIG. 6, and thus, the descriptions therefor will be omitted. Furthermore, step S48 to step S51 are the same as step S28 to step S31 in FIG. 8, and thus, the descriptions therefor will be omitted.

It is further noted here that the display control part 113 may display, in the design drawing, an arrow icon connecting a start point and a finish point to each other after step S50.

Subsequently, in step S52, the display control part 113 displays a distance between a start point and a finish point in the vicinity of an arrow icon displayed in a captured image. In this way, the display 23 displays the comparison display screen image 203B illustrated in FIG. 9.

Step S53 is the same as step S13 in FIG. 6, and thus, the descriptions therefor will be omitted.

Conclusively, this configuration includes displaying, in a captured image, a distance between two certain points selected in the captured image. This configuration thus enables presentation of a distance between two desired points in a captured image to a user with high accuracy. The configuration further enables presentation of the distance in each of the X-direction and the Y-direction including a depth (Y-direction). Moreover, this configuration includes calculating the distance between the two points in the design drawing corresponding to the two certain points selected in the captured image, and thus enables calculation of an exact distance. The configuration further includes displaying the calculated distance in the captured image, and thus enables presentation of an exact distance between two desired points in the captured image to the user. The distance may be displayed in both the design drawing and the captured image, may be displayed in one of the design drawing and the captured image, or may be displayed in another manner.

A part of or a whole of the functions of the device according to each embodiment of the present disclosure may be implemented by a processor, such as a CPU executing a program.

Numerical values used above are merely illustrative to be used to specifically describe the present disclosure, and thus the present disclosure is not limited to the illustrative numerical values.

Order in which steps shown in the flowcharts are executed is merely illustrative to be used to specifically describe the present disclosure, and thus steps may be executed in order other than the above order as long as similar effects are obtained. Some of the steps may be executed simultaneously with (in parallel to) other steps.

The technology according to the disclosure enables presentation of a distance between two desired points in a captured image to a user with high accuracy, and thus is useful as a technology to recognize a distance, or a size or dimension on a site.

1. An information processing method to be executed by a computer, comprising: displaying, on a display of an information terminal, a captured image obtained by photographing a predetermined space and a bird’s-eye view corresponding to the predetermined space; receiving selection of two certain points in the bird’s-eye view or the captured image; and displaying, in the captured image, a distance between two points in the captured image corresponding to the two certain points selected in the bird’s-eye view, displaying, in the bird’s-eye view, a distance between two points in the bird’s-eye view corresponding to the two certain points selected in the captured image, or displaying, in the captured image, a distance between the two certain points selected in the captured image.

2. The information processing method according to claim 1, wherein the receiving includes receiving the selection of the two certain points in the bird’s-eye view, and the displaying of the distance includes calculating a distance between the two certain points selected in the bird’s-eye view, and displaying, in the captured image, the calculated distance as the distance between the two points in the captured image.

3. The information processing method according to claim 1, wherein the receiving includes receiving the selection of the two certain points in the captured image, and the displaying of the distance includes calculating the distance between the two points in the bird’s-eye view corresponding to the two certain points selected in the captured image, and displaying the calculated distance in the bird’s-eye view.

4. The information processing method according to claim 1, wherein the receiving includes receiving the selection of the two certain points in the captured image, and the displaying of the distance includes calculating the distance between the two points in the bird’s-eye view corresponding to the two certain points selected in the captured image, and displaying the calculated distance in the captured image.

5. The information processing method according to claim 1, wherein the captured image includes an omnidirectional image.

6. The information processing method according to claim 5, wherein the displaying of the captured image and the bird’s-eye view includes, in a case where a sightline direction in the captured image is changed, rotating the bird’s-eye view so that the sightline direction agrees with, in the bird’s-eye view, a direction toward an upper side of the bird’s-eye view.

7. The information processing method according to claim 1, wherein the displaying of the captured image and the bird’s-eye view includes displaying one captured image among a plurality of captured images having been continuously captured, the information processing method further comprising displaying a switch icon for switching from the one captured image being displayed to a captured image captured before the one captured image or to a captured image captured after the one captured image, wherein the displaying of the distance includes, in a case where the switch icon is selected, switching to the captured image captured before the one captured image or to the captured image captured after the captured image, and displaying the distance in the captured image resulting from the switching.

8. The information processing method according to claim 1, wherein
the bird’s-eye view includes a two-dimensional plan view of the predetermined space, and
the receiving includes receiving the selection of the two certain points in a horizontal direction in the two-dimensional plan view.

9. The information processing method according to claim 1, wherein the bird’s-eye view includes a three-dimensional simulation image of the predetermined space or a two-dimensional side view of the predetermined space, and the receiving includes receiving the selection of the two certain points in a vertical direction in the three-dimensional simulation image or the two-dimensional side view.

10. An information processing device, comprising a processor, the processor being configured to: display, on a display of an information terminal, a captured image obtained by photographing a predetermined space and a bird’s-eye view corresponding to the predetermined space; receive selection of two certain points in the bird’s-eye view or the captured image; and display, in the captured image, a distance between two points in the captured image corresponding to the two certain points selected in the bird’s-eye view, display, in the bird’s-eye view, a distance between two points in the bird’s-eye view corresponding to the two certain points selected in the captured image, or display, in the captured image, a distance between the two certain points selected in the captured image.

11. A non-transitory computer readable recording medium storing an information processing program, comprising causing a computer to display, on a display of an information terminal, a captured image obtained by photographing a predetermined space and a bird’s-eye view corresponding to the predetermined space; receive selection of two certain points in the bird’s-eye view or the captured image; and display, in the captured image, a distance between two points in the captured image corresponding to the two certain points selected in the bird’s-eye view, display, in the bird’s-eye view, a distance between two points in the bird’s-eye view corresponding to the two certain points selected in the captured image, or display, in the captured image, a distance between the two certain points selected in the captured image.
